(19) United States
(12) Patent Application Publication
(10) Pub. No.: US 2025/0159918 A1
(43) Pub. Date: May 15, 2025

(54) GATE ISOLATION FEATURES

(71) Applicant: Taiwan Semiconductor Manufacturing Company, Ltd., Hsinchu (TW)

(72) Inventors: Tzu-Chung Wang, Hsinchu (TW); Chih-Chang Hung, Hsinchu (TW)

(73) Assignee: Taiwan Semiconductor Manufacturing Company, Ltd., Hsinchu (TW)

(21) Appl. No.: 18/505,632

(22) Filed: Nov. 9, 2023

(51) Int. Cl. H01L 29/66; H01L 21/762; H01L 21/8234; H01L 29/06

(52) U.S. Cl. CPC H10D 30/024; H01L 21/76224; H10D 62/021; H10D 62/118; H10D 64/017; H10D 64/021; H10D 84/0158; H10D 84/038

(57) ABSTRACT

Devices with isolated metal structures and methods of fabrication are provided. A method for isolating a metal gate includes forming a gate line over a semiconductor substrate; patterning a mask over the gate line, wherein an opening in the mask is located over a region of the gate line to be removed; performing an etching process through the opening to form a trench; and forming an isolation feature in the trench, wherein the isolation feature is selectively formed with no air gap, with a small air gap, or with a full air gap.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a method, in accordance with some embodiments.

FIG. 2 is a flow chart illustrating a method, in accordance with some embodiments.

FIG. 3 is a flow chart illustrating a method, in accordance with some embodiments.

FIG. 4 is a flow chart illustrating a method, in accordance with some embodiments.

FIG. 5 illustrates a top-down view of a semiconductor device, according to some embodiments.

FIGS. 6-13 are cross-sectional views of a device during successive stages of fabrication of the method of FIGS. 1 and 2, in accordance with some embodiments.

FIG. 14 is a perspective view of a device formed as a result of the method of FIG. 1, 2, or 3.

FIG. 15 is a Y-cut cross-sectional view of the device of FIG. 14, taking along gate structures, at the stage of fabrication of FIG. 11, in accordance with some embodiments.

FIG. 16 is a Y-cut cross-sectional view of the device of FIG. 14, taking along interlayer dielectric material (between gate lines), at the stage of fabrication of FIG. 11, in accordance with some embodiments.

FIG. 17 is an X-cut cross-sectional view of the device of FIG. 14, taking along the trench, at the stage of fabrication of FIG. 11, in accordance with some embodiments.

FIGS. 18-25 are perspective views of a device during successive stages of fabrication of the method of FIGS. 1 and 2, in accordance with some embodiments.

FIG. 26 is a perspective view including a Y-cut cross-sectional view (through source/drain regions) and an X-cut cross-sectional view of a device at the fabrication stage of FIG. 25.

FIG. 27 is a perspective view including a Y-cut cross-sectional view (through a gate structure) and an X-cut cross-sectional view of a device at the fabrication stage of FIG. 25.

FIGS. 28-30 are Y-cut cross-sectional views of alternate embodiments of isolation features, such as at the stage of fabrication of FIG. 13, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain embodiments herein, a “material structure” is a structure that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a structure that is formed of a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of a tungsten structure and a structure formed of tungsten is a structure that is at least 50 wt. %, at least 60 wt. %, at least 75 wt. %, at least 90 wt. %, at least 95 wt. %, or at least 99 wt. % of tungsten.

For the sake of brevity, typical techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many typical processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Presented herein are embodiments of semiconductor devices and of methods for fabricating such devices. Methods described herein may be easily integrated into the current process flow. For example, methods described herein may be integrated into complementary metal-oxide-semiconductor (CMOS) fabrication processes, including fin-FET, nanowire and nanosheet device processes. Methods of multi-functional insulator formation dependent on desired process conditions or device conditions are provided. Further, methods described herein relate to the formation of an isolation feature, such as a “cut-poly” isolation feature or a “cut-metal” isolation feature that divides a gate line, such as a dummy gate line or a metal gate line in two during fabrication. After fabrication, the isolation feature separates metal gate structures from one another.

In certain embodiments herein, an isolation-last processing method, i.e., after metal gate formation, is performed. Specifically, a dummy gate line is formed and then removed to define a gate cavity. A metal gate line is then formed in the gate cavity before being etched or cut to form a “cut-metal” trench. The isolation feature is then formed in the trench. In such embodiments, the isolation feature may be referred to as a cut-metal isolation feature.

In certain embodiments herein, an isolation-first processing method, i.e., before metal gate formation, is performed. Specifically, a dummy gate line is formed. Then, the dummy gate line is then etched or cut to form a “cut-dummy” or “cut-poly” trench. The isolation feature is then formed in the trench. Then, the remaining portions of the dummy gate line are removed to define gate cavities. A metal gate line is then formed in the gate cavities. Specifically, a metal gate structure may be formed in each gate cavity. In such embodiments, the isolation feature may be referred to as a cut-poly or cut-dummy isolation feature.

Embodiments herein provide for forming the isolation feature with a desired device performance and/or a desired process yield condition.

Processing yield suffers when isolation void defects cause drain to gate shorts. Specifically, isolation may be formed with non-desired voids, such as those formed when deposited isolation material merges above an air pocket. Such voids may be exposed during etching and then filled with metal during gate formation. The filled metal causes shorts if the voids are too large. Methods herein may avoid such shorts and improve process yield by reducing or eliminating air gaps in isolation features. More specifically, methods herein may form trenches with a shape that consistently improves the ability to deposit isolation material without voids or air gaps. Also, methods may include selecting a structure of isolation features, i.e., isolation feature shape, to provide the desired improved process yield. Generally, it has been found that an improved device yield and wide process window are achieved when reducing or eliminating air gaps in isolation features.

Device performance may include a low effective capacitance (Ceff). Low effective capacitance may be improved through use of an isolation feature having a full or large void or air pocket. Methods herein may achieve low effective capacitance by forming isolation features with full or large voids or air gaps. More specifically, methods herein may form trenches with a shape that consistently increases the size of voids or air gaps while depositing isolation material to form isolation features.

Further, methods herein may achieve a balance of improved device yield and low effective capacitance by forming isolation features with small voids or air gaps. More specifically, methods herein may form trenches with a shape that provides for consistently forming isolation features with relatively smaller voids or air gaps.

Also, in embodiments in which air gaps are formed in isolation features, the location of the air gaps may be fined-tuned by modifying the shape of the trench in which the isolation feature is formed. For example, a selected depth of the air gap may be identified and the trench may be etched to a shape such that, when the trench filled with isolation material, an air gap is formed at the selected depth.

In certain embodiments, the isolation feature may be a single-layer film or a multi-layer film. For multi-layer films, the isolation feature may be formed from one material or from different materials. Use of multi-layer films to form isolation features in conjunction with air gaps of selected sizes may provide for achieving specific device requirements.

Embodiments of the present disclosure offer advantages over the existing art, though it is understood that other embodiments may offer different advantages, not all advantages are necessarily discussed herein, and no particular advantage is required for all embodiments.

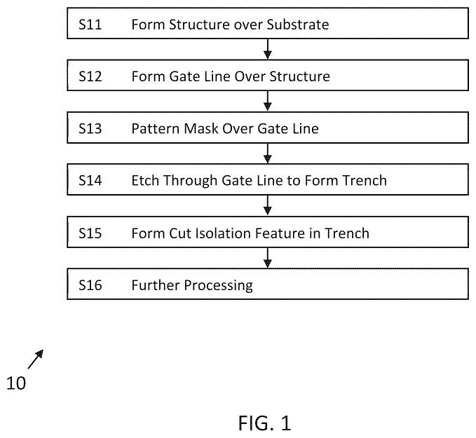

Referring now to FIG. 1, a method 10 is illustrated. In FIG. 1, method 10 includes, at operation S11, forming a structure over a substrate. The structure may include a fin structure formed from a portion of a substrate and from layers overlying the substrate, such as during the formation of a fin structure to be processed into a gate-all-around (GAA) device.

At operation S12, method 10 includes forming a gate line over the structure. In some embodiments, the gate line may be formed from a sacrificial material to be removed during later processing, such as polysilicon. In some embodiments, the gate line may be formed from a non-sacrificial material, such as metal used in forming metal gate structures.

At operation S13, method 10 includes patterning a mask over the gate line. Specifically, the mask may be patterned to form an opening or openings directly over, i.e., vertically over, portions of the gate line to be removed.

At operation S14, method 10 includes etching through the gate line to form a trench. For example, an etch process may be performed to remove the portion or portions of the gate line lying directly under the opening or openings in the mask. Each opening may completely separate the gate line into two adjacent gate line portions. In other words, no remaining portion of the gate line extends between adjacent gate line portions. Further, the etch process may extend below the gate line, such as into an underlying shallow trench isolation (STI) feature, or into an underlying semiconductor substrate.

At operation S15, method 10 includes forming a cut isolation feature in the trench. For example, method 10 may deposit a single layer of an isolation material, multiple layers of an isolation material, or multiple layers of at least two isolation materials. In embodiments, each layer of isolation material is conformally deposited. In certain embodiments, the isolation material merges at a selected height to enclose an air pocket in the isolation feature. In other embodiments, merger of the isolation material at upper heights is avoided to prevent formation of air pockets.

Method 10 may include further processing at operation S16 to complete fabrication of the semiconductor device or integrated circuit. For example, the further processing may include forming interlayer dielectric and metallization layers, forming source/drain contacts to the source/drain regions, and forming source/drain vias and gate vias, in accordance with some embodiments.

It is understood that method 10 includes steps having features of a complementary metal-oxide-semiconductor (CMOS) technology process flow and thus, are only described briefly herein. Also, additional steps may be performed before, after, and/or during method 10.

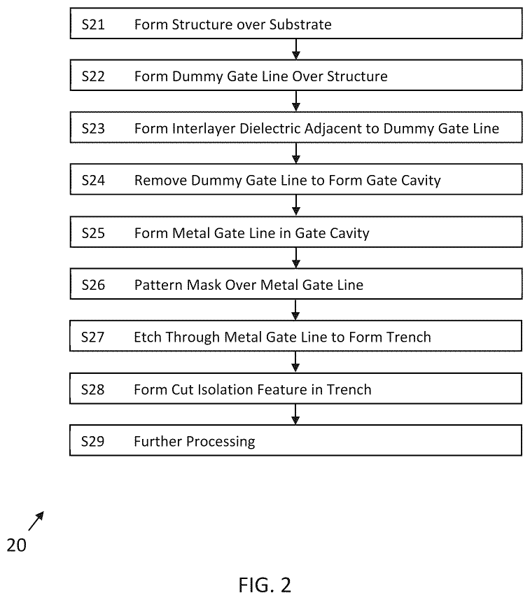

Referring now to FIG. 2, a method 20 is illustrated. Method 20 includes, at operation S21, forming a structure over a substrate. The structure may include a fin structure formed from a portion of a substrate and from layers overlying the substrate, such as during the formation of a fin structure to be processed into a gate-all-around (GAA) device.

At operation S22, method 20 includes forming a dummy gate line over the structure. Specifically, the dummy gate line is formed from sacrificial material to be removed during later processing, such as polysilicon.

At operation S23, method 20 includes forming an interlayer dielectric material adjacent to the dummy gate line.

At operation S24, method 20 includes removing the dummy gate line to form a gate cavity. Specifically, the gate cavity is located between and bounded by the interlayer dielectric material.

At operation S25, method 20 includes forming a metal gate line in the gate cavity. For example, parallel metal gate lines may be formed in parallel gate cavities.

At operation S26, method 20 includes patterning a mask over the metal gate line. Specifically, the mask may be patterned to form an opening or openings directly over, i.e., vertically over, portions of the metal gate line to be removed.

At operation S27, method 20 includes etching through the metal gate line to form a trench. For example, an etch process may be performed to remove the portion or portions of the metal gate line lying directly under the opening or openings in the mask. Each opening may completely separate the metal gate line into two adjacent metal gate line portions or metal gate structures. In other words, no remaining portion of the metal gate line extends between adjacent metal gate line portions or metal gate structures. Further, the etch process may extend below the metal gate line, such as into an underlying shallow trench isolation (STI) feature, or into an underlying semiconductor substrate.

At operation S28, method 20 includes forming a cut-metal isolation feature in the trench. For example, method 10 may deposit a single layer of an isolation material, multiple layers of an isolation material, or multiple layers of at least two isolation materials. In embodiments, each layer of isolation material is conformally deposited. In certain embodiments, the isolation material merges at a selected height to enclose an air pocket in the isolation feature. In other embodiments, merger of the isolation material at upper heights is avoided to prevent formation of air pockets.

Method 20 may include further processing at operation S29 to complete fabrication of the semiconductor device or integrated circuit. For example, the further processing may include forming interlayer dielectric and metallization layers, forming source/drain contacts to the source/drain regions, and forming source/drain vias and gate vias, in accordance with some embodiments.

It is understood that method 20 includes steps having features of a complementary metal-oxide-semiconductor (CMOS) technology process flow and thus, are only described briefly herein. Also, additional steps may be performed before, after, and/or during method 20.

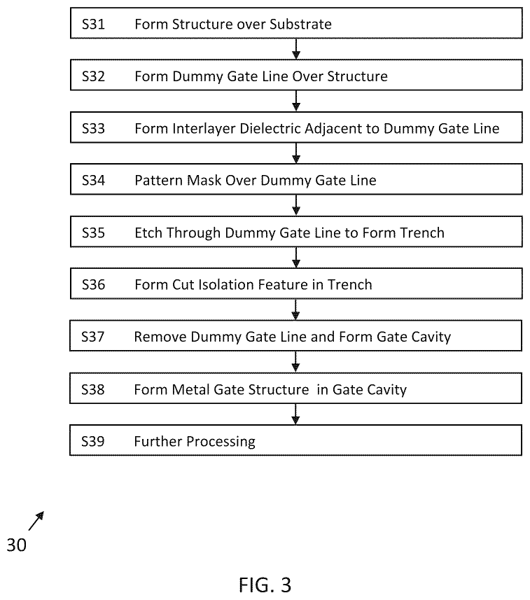

Referring now to FIG. 3, a method 30 is illustrated. Method 30 includes, at operation S31, forming a structure over a substrate. The structure may include a fin structure formed from a portion of a substrate and from layers overlying the substrate, such as during the formation of a fin structure to be processed into a gate-all-around (GAA) device.

At operation S32, method 30 includes forming a dummy gate line over the structure. Specifically, the dummy gate line is formed from sacrificial material to be removed during later processing, such as polysilicon.

At operation S33, method 30 includes forming an interlayer dielectric material adjacent to the dummy gate line.

At operation S34, method 30 includes patterning a mask over the dummy gate line. Specifically, the mask may be patterned to form an opening or openings directly over, i.e., vertically over, portions of the dummy gate line to be removed and replaced with isolation features.

At operation S35, method 30 includes etching through the dummy gate line to form a trench. For example, an etch process may be performed to remove the portion or portions of the dummy gate line lying directly under the opening or openings in the mask. Each opening may completely separate the dummy gate line into two adjacent dummy gate line portions. In other words, no remaining portion of the dummy gate line extends between adjacent dummy gate line portions. Further, the etch process may extend below the dummy gate line, such as into an underlying shallow trench isolation (STI) feature, or into an underlying semiconductor substrate.

At operation S36, method 30 includes forming a cut isolation feature, i.e., a cut-dummy or cut-poly isolation feature, in the trench. For example, method 10 may deposit a single layer of an isolation material, multiple layers of an isolation material, or multiple layers of at least two isolation materials. In embodiments, each layer of isolation material is conformally deposited. In certain embodiments, the isolation material merges at a selected height to enclose an air pocket in the isolation feature. In other embodiments, merger of the isolation material at upper heights is avoided to prevent formation of air pockets.

At operation S37, method 30 includes removing the remaining portion or portions of the dummy gate line to form a gate cavity or gate cavities. Specifically, the gate cavity is located between and bounded by adjacent cut isolate features and the interlayer dielectric material.

At operation S38, method 30 includes forming a metal gate structure in each gate cavity.

Method 30 may include further processing at operation S39 to complete fabrication of the semiconductor device or integrated circuit. For example, the further processing may include forming interlayer dielectric and metallization layers, forming source/drain contacts to the source/drain regions, and forming source/drain vias and gate vias, in accordance with some embodiments.

It is understood that method 30 includes steps having features of a complementary metal-oxide-semiconductor (CMOS) technology process flow and thus, are only described briefly herein. Also, additional steps may be performed before, after, and/or during method 30.

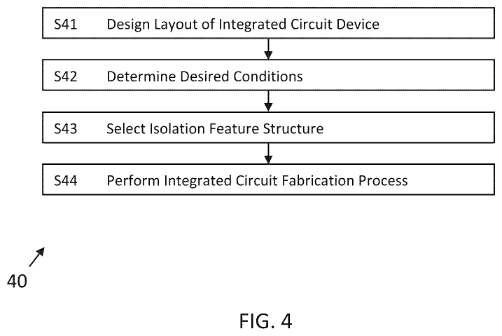

Referring now to FIG. 4, a method 40 is illustrated. Method 40 includes, at operation S41, designing a layout of a semiconductor or an integrated circuit device. In some certain embodiments, the device includes a first gate structure and a second gate structure separated by an isolation feature. The device may be a GAA device.

At operation S42, method 40 includes determining a desired device performance condition and/or a desired process yield condition. For example, device yield may be prioritized and a minimum device yield may be selected as the desired process yield condition. Alternatively, a desired device performance condition, such as effective capacitance, may be selected. In other embodiments, a relatively lower minimum device yield and a relatively higher effective capacitance may be selected as the desired conditions.

At operation S43, method 40 includes selecting a structure of the isolation feature to provide the desired condition. In some embodiments, the structure of the isolation feature comprises a selected shape.

At operation S44, method 40 includes performing an integrated circuit fabrication process. The integrated circuit fabrication process may be described as method 10, method 20 or method 30 above The integrated circuit fabrication process may include forming a gate line over a semiconductor substrate; performing an etching process to remove a portion of the gate line and form a trench with the selected shape; and forming an isolation feature in the trench. The isolation feature may be selectively formed with no air gap, with a small air gap, or with a full air gap.

It is understood that method 40 includes steps having features of a complementary metal-oxide-semiconductor (CMOS) technology process flow and thus, are only described briefly herein. Also, additional steps may be performed before, after, and/or during method 40.

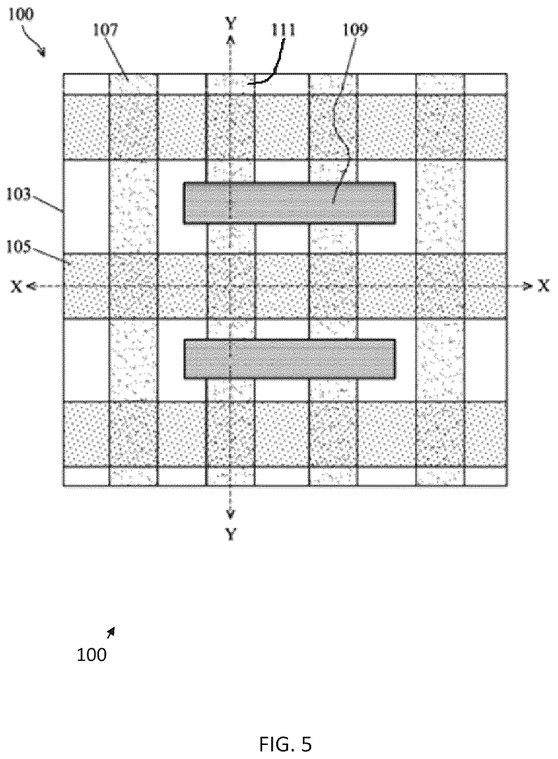

Referring to FIG. 5, an overhead view of a semiconductor or integrated circuit device 100 is provided. In FIG. 5, the device 100 includes a multi-layer structure 103 comprising a plurality of nanosheets formed over a semiconductor substrate 201 (illustrated in the following figures), fins 105 formed in the multi-layer structure 103, and a plurality of gate electrodes 107 in the form of gate lines 111 over the fins 105. FIG. 5 further illustrates a plurality of isolation features 109 separating two of the gate lines 111.

Although three fins 105 are illustrated in FIG. 5 and in the following figures, it is understood that depending on the desired design and number of the GAA semiconductor devices 100, any suitable number of fins 105 may be formed in the multi-layer structure 103 to form the desired GAA semiconductor devices 100. Furthermore, any suitable number of gate electrodes 107/gate lines 111 and isolation features 109 may be formed to form the desired GAA semiconductor devices 100.

In FIG. 5, the X-axis extends through the length of the fin 105. Further, the Y-axis extends through the length of a gate line 111 that has been separated by the two isolation features 109, and through the two isolation features 109. The following cross-sectional views are taken along the Y-axis.

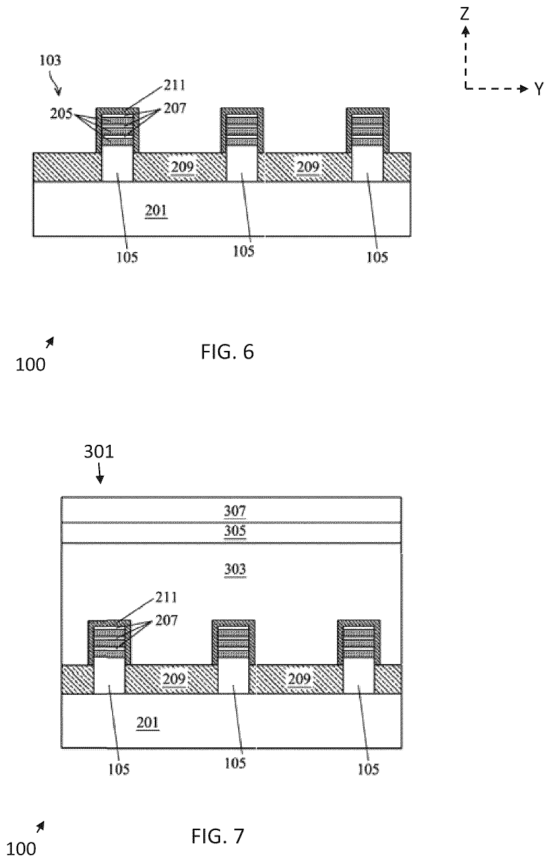

FIGS. 6-13 illustrate operations in accordance with method 10 and method 20 for forming the device 100 of FIG. 5 described above. Specifically, an isolation-last processing method, i.e., after metal gate formation, is performed.

Referring now to FIG. 6, a method for fabricating a semiconductor device 100 includes forming a multi-layer structure 103 over a semiconductor material, such as a substrate, and forming structures 105 such as fins 105 in the multi-layer structure 103, in accordance with some embodiments.

In an embodiment the substrate 201 is a semiconductor substrate, which may be, for example, a silicon substrate, a silicon germanium substrate, a germanium substrate, a III-V material substrate (e.g., GaAs, GaP, GaAsP, AlInAs, AlGaAs, GaInAs, InAs, GaInP, InP, InSb, and/or GaInAsP; or a combination thereof), or a substrate formed of other semiconductor materials with, for example, high band-to-band tunneling (BTBT). The substrate 201 may be doped or un-doped. In some embodiments, the substrate 201 may be a bulk semiconductor substrate, such as a bulk silicon substrate that is a wafer, a semiconductor-on-insulator (SOI) substrate, a multi-layered or gradient substrate, or the like.

FIG. 6 illustrates a deposition process to form the multi-layer structure 103 in an intermediate stage of manufacturing the GAA semiconductor device 100, according to some embodiments. In particular, FIG. 6 further illustrates a series of depositions that are performed to form a multi-layer stack 203 of alternating materials of first layers 205 and second layers 207 over the substrate 201.

According to some embodiments, the first layers 205 may be formed using a first semiconductor material with a first lattice constant, such as SiGe, Ge, Si, GaAs, InSb, GaSb, InAlAs, InGaAs, GaSbP, GaAsSb, combinations of these, or the like. In some embodiments, a first layer 205 of the first semiconductor material (e.g., SiGe) is epitaxially grown on the substrate 201 using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer CVD (ALCVD), ultrahigh vacuum CVD (UHVCVD), reduced pressure CVD (RPCVD), a combination thereof, or the like, may also be utilized. In some embodiments, the first layer 205 is formed to thicknesses of from about 3 nm and about 10 nm. However, any suitable thickness may be utilized while remaining within the scope of the embodiments.

After the first layer 205 has been formed over the substrate 201, a second layer 207 may be formed over the first layer 205. According to some embodiments, the second layers 207 may be formed using a second semiconductor material such as Si, SiGe, Ge, GaAs, InSb, GaSb, InAlAs, InGaAs, GaSbP, GaAsSb, combinations of these, or the like with a second lattice constant that is different from the first lattice constant of the first layer 205. In a particular embodiment in which the first layer 205 is silicon germanium, the second layer 207 is a material such as silicon. However, any suitable combination of materials may be utilized for the first layers 205 and the second layers 207.

In some embodiments, the second layer 207 is epitaxially grown on the first layer 205 using a deposition technique similar to that used to form the first layer 205. However, the second layer 207 may use any of the deposition techniques suitable for forming the first layer 205, as set forth above or any other suitable technique. According to some embodiments, the second layer 207 is formed to a similar thickness to that of the first layer 205. However, the second layer 207 may also be formed to a thickness that is different from the first layer 205. According to some embodiments, the second layer 207 may be formed to a thickness of from about 5 nm and about 15 nm. However, any suitable thickness may be used.

After forming the second layer 207 over the first layer 205, the deposition process is repeated to form the remaining material layers in the series of alternating materials of the first layers 205 and the second layers 207 until a desired topmost layer of the multi-layer stack 203 has been formed. According to the present embodiment, the first layers 205 may be formed to a same or similar first thickness and the second layers 207 may be formed to the same or similar second thickness. However, the first layers 205 may have different thicknesses from one another and/or the second layers 207 may have different thicknesses from one another and any combination of thicknesses may be used for the first layers 205 and the second layers 207. According to the present embodiment, the topmost layer of the multi-layer stack 203 is formed as a second layer 207; however, in other embodiments, the topmost layer of the multi-layer stack 203 may be formed as a first layer 205. Additionally, although embodiments are disclosed herein comprising three of the first layers 205 and three of the second layers 207, the multi-layer stack 203 may have any suitable number of layers (e.g., nanosheets). For example, the multi-layer stack 203 may comprise from two to ten nanosheets. In some embodiments, the multi-layer stack 203 may comprise equal numbers of the first layers 205 to the second layers 207; however, in other embodiments, the number of the first layers 205 may be different from the number of the second layers 207. According to some embodiments, the multi-layer stack 203 may be formed to a height of from about 12 nm to about 100 nm. However, any suitable height may be used.

FIG. 6 further illustrates, a patterning process of the multi-layer structure 103 and a formation of isolation regions 209, such as shallow trench isolation (STI) regions in an intermediate stage of manufacturing the GAA semiconductor device 100, in accordance with some embodiments. The patterning process is used to form fins 105 in the multi-layer structure 103 and to form trenches between the fins 105 in preparation for forming the isolation regions 209. The patterning process for forming the fins 105, according to some embodiments, comprises applying a photoresist over the multi-layer stack 203 and then patterning and developing the photoresist to form a mask over the multi-layer stack 203. After being formed, the mask is then used during an etching process, such as an anisotropic etching process to transfer the pattern of the mask into the underlying layers to form the trenches through the multi-layer stack 203 and into the substrate 201 to define the fins 105, wherein the fins 105 are separated by the trenches.

Additionally, while a single mask process has been described, this is intended to be illustrative and is not intended to be limiting, as the gate all around (GAA) device structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

In an embodiment, the isolation regions 209 are formed as shallow trench isolation regions by depositing a dielectric material in the trenches. According to some embodiments, the dielectric material used to form the isolation regions 209 may be a material such as an oxide material (e.g., a flowable oxide), high-density plasma (HDP) oxide, or the like. The dielectric material may be formed, after an optional cleaning and lining of the trenches, using either a chemical vapor deposition (CVD) method (e.g., the HARP process), a high density plasma CVD method, or other suitable method of formation to fill or overfill the regions around the fins 105. In some embodiments, a post placement anneal process (e.g., oxide densification) is performed to densify the material of the isolation regions 209 and to reduce its wet etch rate. A chemical mechanical polishing (CMP), an etch, a combination of these, or the like may be performed to remove any excess material of the isolation regions 209.

After the dielectric material has been deposited to fill or overfill the regions around the fins 105, the dielectric material may then be recessed away from the surface of the fins 105 to form the isolation regions 209. The recessing may be performed to expose at least a portion of the sidewalls of the fins 105 adjacent to the top surface of the fins 105. The dielectric material may be recessed using a wet etch by dipping the top surface of the fins 105 into an etchant selective to the material of the dielectric material, although other methods, such as a reactive ion etch, a dry etch, chemical oxide removal, or dry chemical clean may be used.

FIG. 6 further illustrates the formation of a dummy gate dielectric 211 over the exposed portions of the fins 105. After the isolation regions 209 have been formed, the dummy gate dielectric 211 may be formed by thermal oxidation, chemical vapor deposition, sputtering, or any other methods known and used in the art for forming a gate dielectric. Depending on the technique of gate dielectric formation, the dummy gate dielectric 211 thickness on the top may be different from the dummy dielectric thickness on the sidewall. In some embodiments, the dummy gate dielectric 211 may be formed by depositing a material such as silicon and then oxidizing or nitridizing the silicon layer in order to form a dielectric such as the silicon dioxide or silicon oxynitride. In such embodiments, the dummy gate dielectric 211 may be formed to a thickness of from about 3 Å to about 100 Å, such as about 10 Å. In other embodiments, the dummy gate dielectric 211 may also be formed from a high permittivity (high-k) material such as lanthanum oxide (La₂O₃), aluminum oxide (Al₂O₃), hafnium oxide (HfO₂), hafnium oxynitride (HfON), or zirconium oxide (ZrO₂), or combinations thereof, with an equivalent oxide thickness of from about 0.5 Å to about 100 Å, such as about 10 Å or less. Additionally, any combination of silicon dioxide, silicon oxynitride, and/or high-k materials may also be used for the dummy gate dielectric 211.

In FIG. 7, the method may continue with forming sacrificial or dummy gate stacks 301 over the fins 105, in accordance with some embodiments. According to some embodiments, the dummy gate stacks 301 comprise a dummy gate dielectric 211, a dummy gate electrode 303 over the dummy gate dielectric 211, a first hard mask 305 over the dummy gate electrode 303, and a second hard mask 307 over the first hard mask 305.

In some embodiments, the dummy gate electrode 303 comprises a conductive material and may be selected from a group comprising of polysilicon, W, Al, Cu, AlCu, W, Ti, TiAlN, TaC, TaCN, TaSiN, Mn, Zr, TiN, Ta, TaN, Co, Ni, combinations of these, or the like. The dummy gate electrode 303 may be deposited by chemical vapor deposition (CVD), sputter deposition, or other techniques known and used in the art for depositing conductive materials. The thickness of the dummy gate electrode 303 may be from about 5 Å to about 500 Å. The top surface of the dummy gate electrode 303 may have a non-planar top surface, and may be planarized prior to patterning of the dummy gate electrode 303 or gate etch. Ions may or may not be introduced into the dummy gate electrode 303 at this point. Ions may be introduced, for example, by ion implantation techniques.

After the dummy gate electrode 303 has been formed, the dummy gate dielectric 211 and the dummy gate electrode 303 may be patterned. In an embodiment the patterning may be performed by initially forming a first hard mask 305 over the dummy gate electrode 303 and forming the second hard mask 307 over the first hard mask 305.

According to some embodiments, the first hard mask 305 comprises a dielectric material such as silicon nitride (SiN), oxide (OX), silicon oxide (SiO), titanium nitride (TiN), silicon oxynitride (SiON), combinations of these, or the like. The first hard mask 305 may be formed using a process such as chemical vapor deposition, plasma enhanced chemical vapor deposition, atomic layer deposition, or the like. However, any other suitable material and method of formation may be utilized. The first hard mask 305 may be formed to a thickness of from about 20 Å to about 3000 Å, such as about 20 Å.

The second hard mask 307 comprises a separate dielectric material from the material of the first hard mask 305. The second hard mask 307 may comprise any of the materials and use any of the processes suitable for forming the first hard mask 305 and may be formed to a same or similar thickness as the first hard mask 305. In embodiments where the first hard mask 305 comprises silicon nitride (SiN), the second hard mask 307 may be e.g., an oxide (OX). However, any suitable dielectric materials, processes and thicknesses may be used to form the second hard mask.

After the first hard mask 305 and the second hard mask 307 have been formed, the first hard mask 305 and the second hard mask 307 may be patterned. Patterning of the first hard mask 305 and second hard mask 307 occurs in the X-dimension, i.e., distanced into or out of the drawing sheet for the cross-sectional views of FIGS. 6-13. Thereafter, various processes may be performed to form desired structures, etching of the dummy gate material to form distinct dummy gate stacks, formation of spacers, etching of openings for source/drain regions, epitaxial growth of source/drain regions, implant processes, and other typical gate processing.

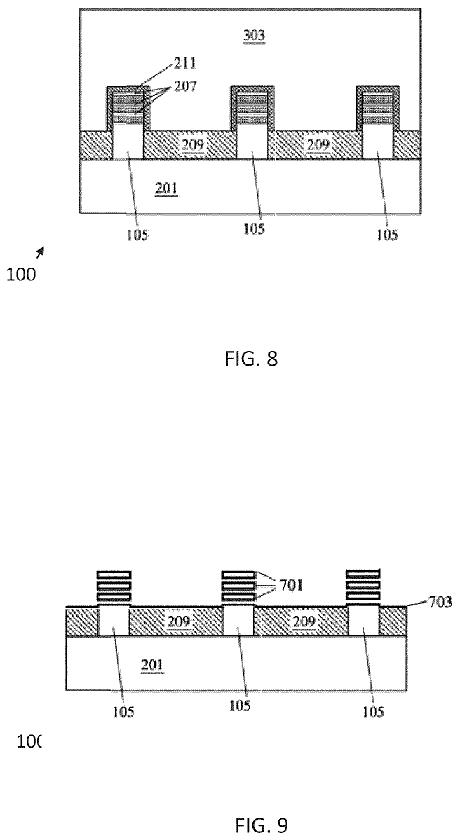

At FIG. 8, the method may continue with removal of the first hard mask 305 and the second hard mask 307. According to some embodiments, one or more etching processes and/or the chemical mechanical planarization (CMP) may be utilized to remove the first hard mask 305 and the second hard mask 307. As such, the dummy gate electrode 303 is exposed after the removal of the first hard mask 305.

At FIG. 9, the method may continue with removing the dummy gate electrode 303 and the dummy gate dielectric 211. FIG. 9 further illustrates a wire-release process to form nanostructures 701, i.e., vertically-spaced nanosheets, from the second layers 207, in accordance with some embodiments. FIG. 9 further illustrates the formation of a gate dielectric 703 over the nanostructures 701, according to some embodiments.

After being exposed by removal of the first hard mask 305, the dummy gate electrode 303 may be removed in order to expose the underlying dummy gate dielectric 211. In an embodiment the dummy gate electrode 303 is removed using, e.g., one or more wet or dry etching process that utilizes etchants that are selective to the material of the dummy gate electrode 303. However, any suitable removal process may be utilized.

After the dummy gate dielectric 211 has been exposed by removal of the dummy gate electrode 303, the dummy gate dielectric 211 may be removed. In an embodiment the dummy gate dielectric 211 may be removed using, e.g., a wet etching process, although any suitable etching process may be utilized.

After the dummy gate dielectric 211 has been removed (which also exposes the sides of the first layers 205), the first layers 205 may be removed from between the substrate 201 and from between the second layers 207 in a wire release process step. The wire release process step may also be referred to as a sheet release process step, a sheet formation process step, a nanosheet formation process step or a wire formation process step. In an embodiment the first layers 205 may be removed using a wet etching process that selectively removes the material of the first layers 205 (e.g., silicon germanium (SiGe)) without significantly removing the material of the substrate 201 and the material of the second layers 207 (e.g., silicon (Si)). However, any suitable removal process may be utilized.

For example, in an embodiment, an etchant such as a high temperature HCl may be used to selectively remove the material of the first layers 205 (e.g., SiGe) without substantively removing the material of the substrate 201 and/or the material of the second layers 207 (e.g., Si). Additionally, the wet etching process may be performed at a temperature of from 400° C. to about 600° C., such as about 560° C., and for a time of from about 100 seconds to about 600 seconds, such as about 300 seconds. However, any suitable etchant, process parameters, and time can be utilized.

By removing the material of the first layers 205, the sides of the second layers 207 (relabeled nanostructures 701 in FIG. 9) are exposed. According to some embodiments, the nanostructures 701 are vertically separated or spaced from one another by a spacing of from about 5 nm to about 15 nm, such as about 10 nm. The nanostructures 701 comprise the channel regions between opposite ones of the source/drain regions 503 and have a channel length (in the X-direction into and out of the drawing sheet) of from about 5 nm to about 180 nm, such as about 10 nm, and a channel width, in the Y-direction, of from about 8 nm to about 100 nm, such as about 30 nm. In an embodiment the nanostructures 701 are formed to have the same thicknesses as the original thicknesses of the second layers 207 such as from about 3 nm to about 15 nm, such as about 8 nm, although the etching processes may also be utilized to reduce the thicknesses.

In some embodiments, the wire release step may include an optional step for the partial removal of the material of the second layers 207 (e.g., by over etching) during removal of the first layers 205. As such, the thicknesses of the nanostructures 701 are formed to have reduced thicknesses as compared to the original thickness of the second layers 207. As such, the nanostructures 701 may have thicknesses that are less than the thicknesses of the original second layers 207.

Although FIG. 9 illustrates the formation of three of the nanostructures 701, any suitable number of the nanostructures 701 may be formed from the nanosheets provided in the multi-layer stack 203. For example, the multi-layer stack 203 may be formed to include any suitable number of the first layers 205 and any suitable number of the second layers 207. As such, a multi-layer stack 203 comprising fewer first layers 205 and fewer second layers 207, after removal of the first layers 205, forms one or two of the nanostructures 701. Whereas, a multi-layer stack 203 comprising many of the first layers 205 and many of the second layers 207, after removal of the first layers 205, forms four or more of the nanostructures 701.

FIG. 6 further illustrates the formation of the gate dielectric 703 over the nanostructures 701, according to some embodiments. In an embodiment the gate dielectric 703 comprises a high-k material (e.g., K greater than or equal to 9) such as Ta₂O₅, Al₂O₃, Hf oxides, Ta oxides, Ti oxides, Zr oxides, Al oxides, La oxides (e.g., HfO₂, HfSiO, HfSiON, HfTaO, HfTiO, HfZrO, LaO, ZrO, TiO), combinations of these, or the like, deposited through a process such as atomic layer deposition, chemical vapor deposition, or the like. In some embodiments, the gate dielectric 703 comprises a nitrogen doped oxide dielectric that is initially formed prior to forming a metal content high-K (e.g., K value>13) dielectric material. The gate dielectric 703 may be deposited to a thickness of from about 1 nm to about 3 nm, although any suitable material and thickness may be utilized. In certain embodiments, the gate dielectric 703 wraps around the nanostructures 701, thus forming channel regions between the source/drain regions.

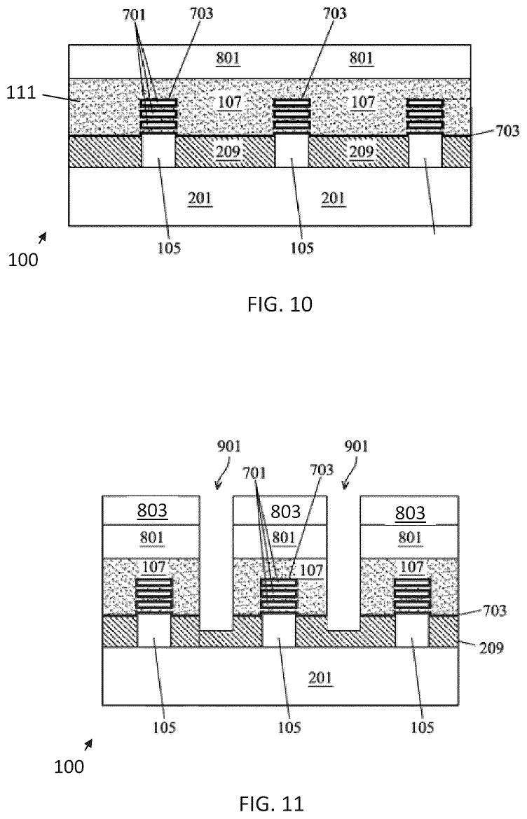

At FIG. 10, the method may continue with forming a metal gate line 111 (shown in FIG. 5) over the fin structures. For example, method 10 includes forming gate electrodes 107 and gate caps 801, that form the metal gate line, in accordance with some embodiments. After the gate dielectric 703 has been formed, the gate electrodes 107 are formed to surround the nanostructures 701. For example, inter-sheet portions of the metal gate are located between the nanosheets 701.

In some embodiments, the gate electrodes 107 are formed using multiple layers, each layer deposited sequentially adjacent to each other using a highly conformal deposition process such as atomic layer deposition, although any suitable deposition process may be utilized. According to some embodiments, the gate electrodes 107 may comprise a capping layer, a barrier layer, an n-metal work function layer, a p-metal work function layer, and a fill material.

The capping layer may be formed adjacent to the gate dielectric 703 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as atomic layer deposition, chemical vapor deposition, or the like, although any suitable deposition process may be used.

The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

The n-metal work function layer may be formed adjacent to the barrier layer. In an embodiment the n-metal work function layer is a material such as W, Cu, AlCu, TiAlC, TiAlN, TiAl, Pt, Ti, TiN, Ta, TaN, Co, Ni, Ag, Al, TaAl, TaAlC, TaC, TaCN, TaSiN, Mn, Zr, other suitable n-type work function materials, or combinations thereof. For example, the first n-metal work function layer may be deposited utilizing an atomic layer deposition (ALD) process, CVD process, or the like. However, any suitable materials and processes may be utilized to form the n-metal work function layer.

The p-metal work function layer may be formed adjacent to the n-metal work function layer. In an embodiment, the first p-metal work function layer may be formed from a metallic material such as W, Al, Cu, TiN, Ti, TiAlN, TiAl, Pt, Ta, TaN, Co, Ni, TaC, TaCN, TaSiN, TaSi₂, NiSi₂, Mn, Zr, ZrSi₂, TaN, Ru, AlCu, Mo, MoSi₂, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. Additionally, the p-metal work function layer may be deposited using a deposition process such as atomic layer deposition, chemical vapor deposition, or the like, although any suitable deposition process may be used.

After the p-metal work function layer has been formed, the fill material is deposited to fill a remainder of the opening. In an embodiment the fill material may be a material such as tungsten, Al, Cu, AlCu, W, Ti, TiAlN, TiAl, Pt, TaC, TaCN, TaSiN, Mn, Zr, TiN, Ta, TaN, Co, Ni, combinations of these, or the like, and may be formed using a deposition process such as plating, chemical vapor deposition, atomic layer deposition, physical vapor deposition, combinations of these, or the like. However, any suitable material may be utilized.

After the openings left behind by the removal of the dummy gate electrode 303 have been filled, the materials of the gate electrode 107 and the gate dielectric 703 may be planarized in order to remove any material that is outside of the openings left behind by the removal of the dummy gate electrode 303. In a particular embodiment the removal may be performed using a planarization process such as chemical mechanical polishing, although any suitable planarization and removal process may be utilized. According to some embodiments, the gate electrodes may be formed to a length of from about 8 nm to about 30 nm. However, any suitable length may be used.

After being formed, the gate electrodes 107 may be recessed. According to some embodiments, the gate electrodes 107 may be recessed using an etching process such as a wet etch, a dry etch, combinations, or the like. After being recessed, the height of the gate electrodes 107 above a topmost one of the nanostructures 701 is a height such as from about 8 nm to about 30 nm. However, any suitable height may be used.

The gate caps 801 may be formed by initially depositing a dielectric material over the gate electrodes 107 to fill and/or overfill the recesses. In some embodiments, the gate caps 801 are formed using a dielectric material such as a silicon nitride (SiN), oxide (OX), silicon oxynitride (SiON), silicon oxycarbonitride (SiOCN), silicon carbonitride (SiCN), or the like. According to some embodiments, the gate caps 801 are formed using a metal oxide of materials such as zirconium (Zr), hafnium (Hf), aluminum (Al), or the like. Furthermore, the gate caps 801 may be formed using a suitable deposition process such as chemical vapor deposition (CVD), atomic layer deposition (ALD), physical vapor deposition (PVD), combinations of these, or the like. However, any suitable materials and deposition processes may be utilized. After being deposited, the gate caps 801 may be planarized using a planarization process such as a chemical mechanical polishing process. After being planarized, the gate caps 801 have a vertical thickness of from about 10 nm to about 30 nm. However, any suitable thickness may be used.

At FIG. 11, the method may continue with forming trenches 901 in a cut-metal gate process, in accordance with some embodiments. After the gate caps 801 have been planarized, a masking layer 803 may be deposited over the planar surfaces of the gate caps 801. After being deposited, the masking layer 803 is patterned to expose the underlying materials including the gate caps 801 in desired locations of the isolation features 109 that are to be formed.

After being patterned, the masking layer 803 is used as an etching mask to etch the underlying materials to form the trenches 901 (e.g., trenches, recesses, channels or the like). In the etching process, the materials of the gate caps 801 and the gate electrodes 107 are etched using an anisotropic etching process. In certain embodiments, the etch process continues through the gate dielectric 703 and into the isolation regions 209. The trenches 901 may be formed between adjacent fins 105 and may be formed to cut through one or more gate electrodes 107. According to some embodiments, two of the trenches 901 are formed to cut through two adjacent gate electrodes 107 and are located on opposite sides of one of the fins 105. After the trenches 901 have been formed, the masking layer 803 may be removed.

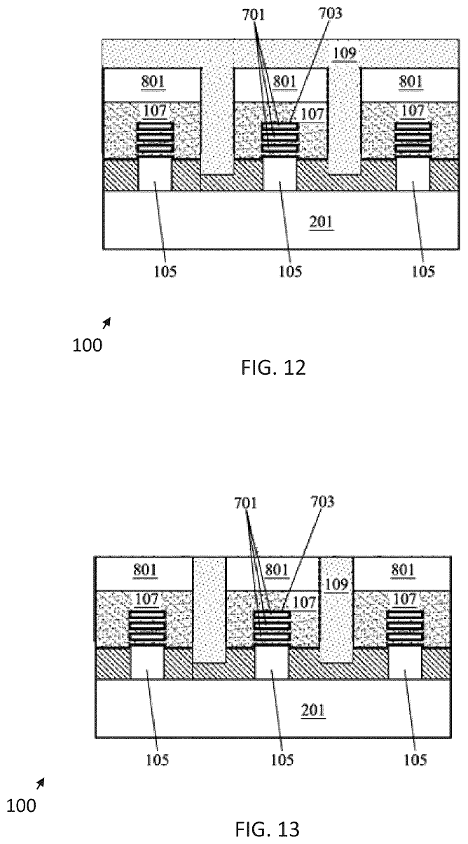

At FIG. 12, the method 10 may continue with forming isolation features 109, in accordance with some embodiments. After the trenches 901 have been formed, the isolation features 109 are formed by initially depositing a dielectric material to fill and overfill the trenches 901. In accordance with some embodiment, the isolation features 109 are formed using any dielectric material and deposition process suitable for forming the gate caps 801. In some embodiments, the dielectric material used to form the isolation features 109 is the same as the dielectric material used to form the gate caps 801, although the dielectric materials may be different. For example, in embodiments where the gate caps 801 are formed using silicon nitride (SiN), the isolation features 109 may also be formed using silicon nitride (SiN) in a deposition process such as Atomic Layer Deposition (ALD). However, any suitable dielectric materials and deposition processes may be used. According to some embodiments, the isolation features 109 are formed to a width of from about 5 nm to about 50 nm, such as about 10 nm. However, any suitable widths may be used.

The isolation features 109 divide the two gate electrodes 107 or lines 111, which are relatively long, into a plurality of segmented gate electrodes 107 which are relatively short and isolate the segmented gate electrodes 107 from one another. Furthermore, the excess dielectric material of the isolation features 109 outside of the trenches 901 may be retained and used as a masking layer in a Continuous Poly On Diffusion Edge (CPODE) process.

At FIG. 13, a chemical mechanical planarization (CMP) process is performed to remove the overburden portion of the isolation material deposited to form the isolation features 109.

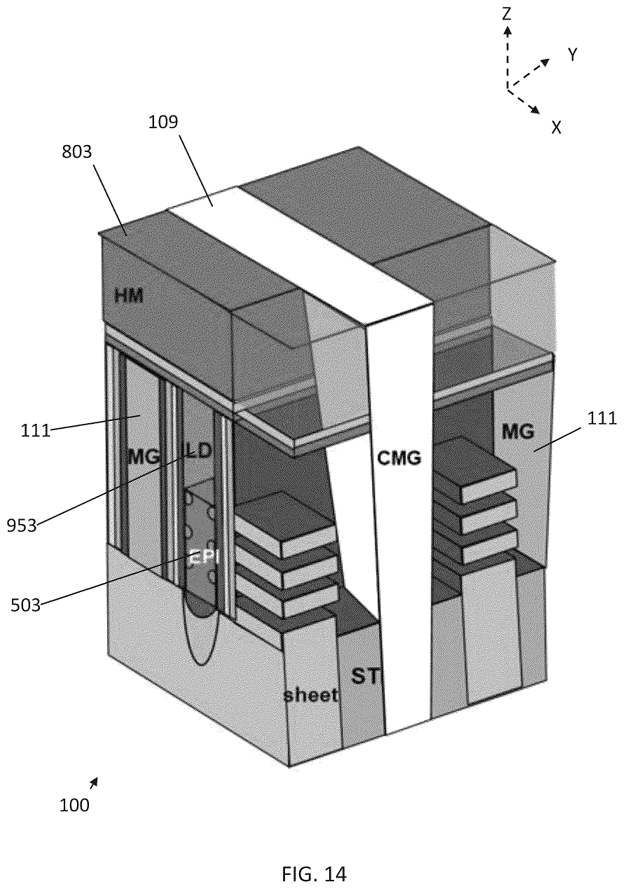

Referring now to FIGS. 14-17, further details of the device 100 are illustrated. FIG. 14 is a perspective view of an embodiment of a device 100, with a portion of a metal gate removed to allow viewing of internal structure. In the embodiment of FIG. 14, the isolation feature 109 has been formed in the trench while the masking layer 803 remains over the device 100. As shown in FIG. 14, two metal gate lines 111 extend in the Y direction and a separated from one another by a source/drain region 503 and an interlayer dielectric (ILD) structure 953 lying over the source/drain region 503. As used herein, “source/drain region(s)” may refer to a source region or a drain region, individually or collectively depending on the context. It is noted that the ILD structure 953 is formed around the dummy gate electrodes and defines the gate cavity during the replacement gate process.

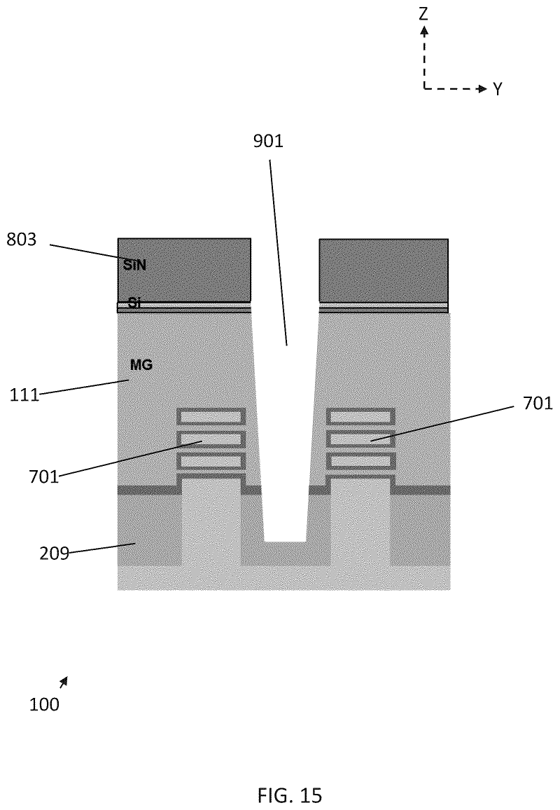

FIG. 15 is a Y-cut cross-sectional view of the device 100 of FIG. 14 taking along a metal gate line 111. FIG. 15 illustrates a stage of fabrication after the trench 901 has been etched and before the isolation feature 109 is formed in the trench 901. As shown, the trench 901 separates two stacks of nanostructures 701.

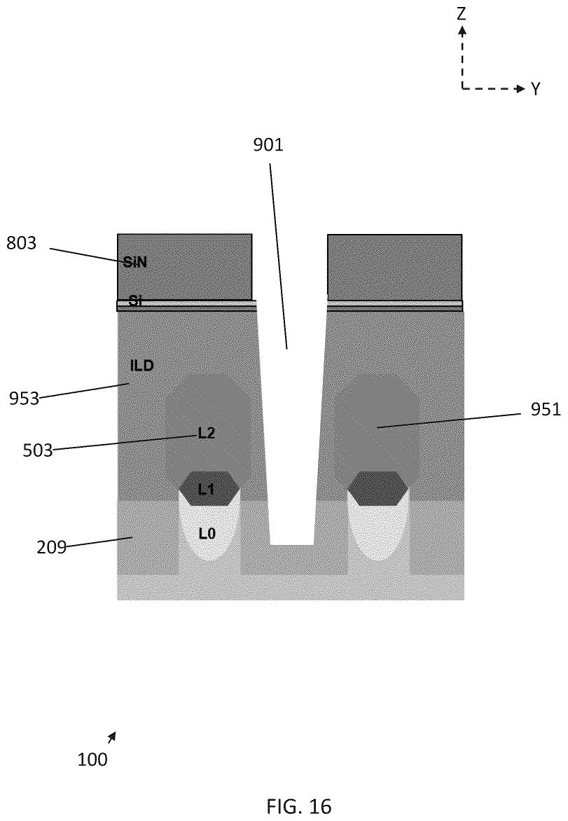

FIG. 16 is a Y-cut cross-sectional view of the device 100 of FIG. 14 taking along an ILD structure 953. FIG. 16 illustrates a stage of fabrication after the trench 901 has been etched and before the isolation feature 109 is formed in the trench 901. As shown, the trench 901 separates two source/drain regions 503.

As shown in FIGS. 15 and 16, the trench 901 extends vertically and laterally completely through the metal gate line 111 and vertically completely through the ILD structure 953 and extends into the underlying shallow trench isolation (STI) regions 209.

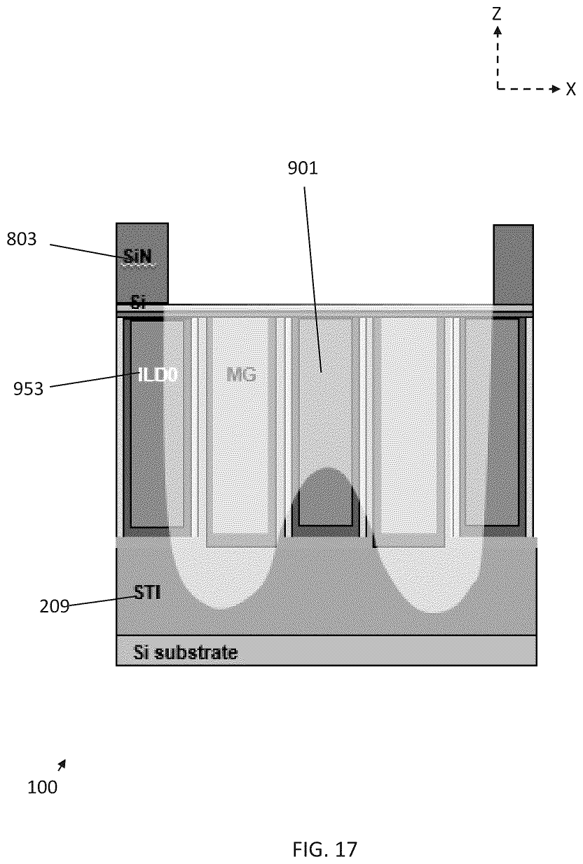

FIG. 17 is an X-cut cross-sectional view of the device 100 of FIG. 14 taking along the trench 901, and illustrating in phantom the adjacent non-etched portion of the device 100. FIG. 17 illustrates a stage of fabrication after the trench 901 has been etched and before the isolation feature 109 is formed in the trench 901.

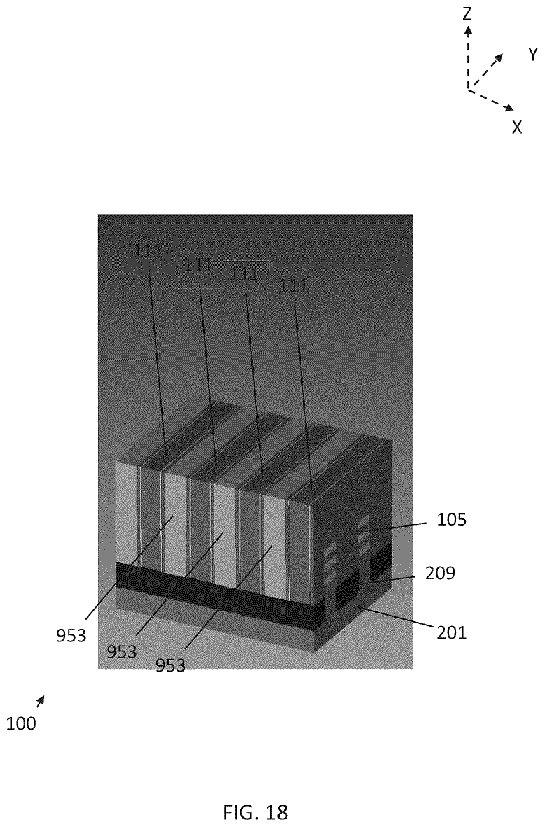

FIGS. 18-24 are perspective views illustrating an embodiment for etching a trench 901 through a gate line 111.

In FIG. 18, four parallel gate lines 111 extend in the Y direction and are separated from one another by ILD structures 953. As shown, the gate lines 111 and ILD structures 953 lie over fins 105 formed over a substrate 201 and separated by STI regions 209.

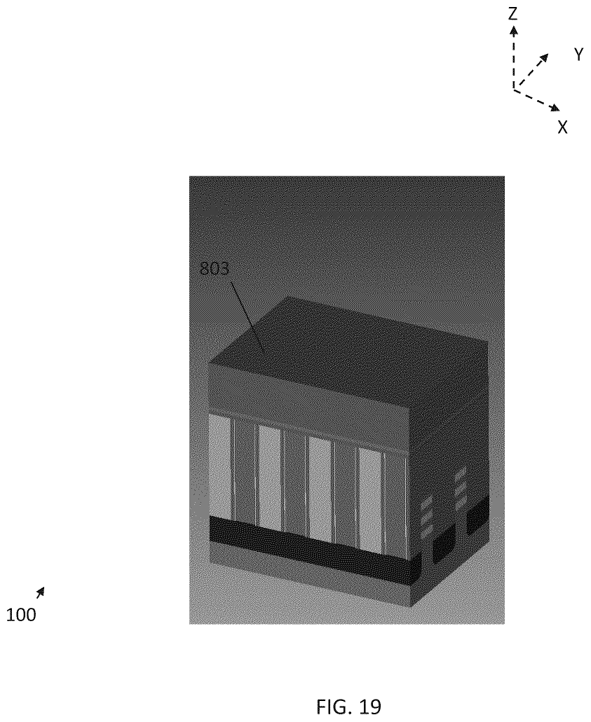

In FIG. 19, a mask 803 is formed over the structure of the device 100 of FIG. 18. The mask may include multiple layers, such as a silicon nitride layer, a silicon layer, and a silicon nitride layer.

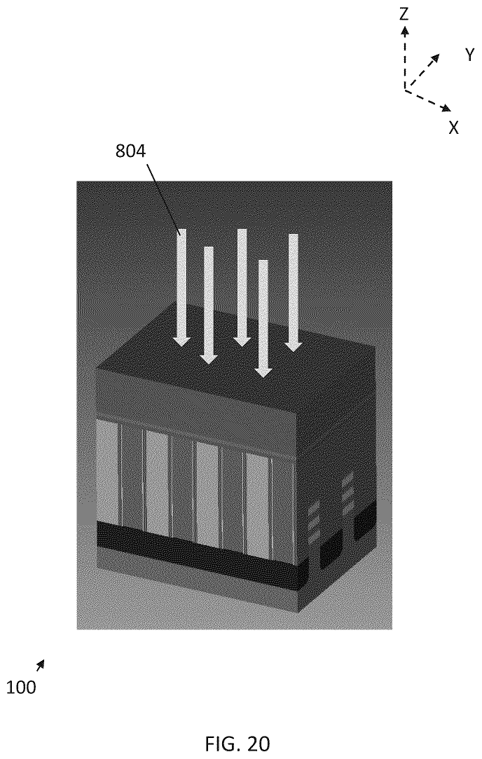

In FIG. 20, a photoresist descum or stripping is performed as indicated by arrows 804.

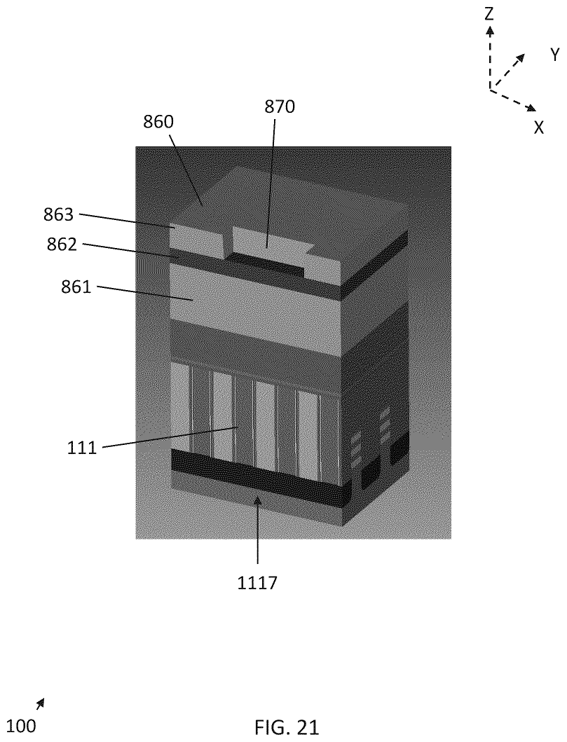

In FIG. 21, a photoresist 860 is formed and patterned over the structure of the device of FIG. 20. As shown, the photoresist 860 includes a bottom layer 861, a middle layer 862, and a top layer 863. The top layer 863 is patterned with an opening 870 overlying regions 1117 of the gate lines 111 to be removed.

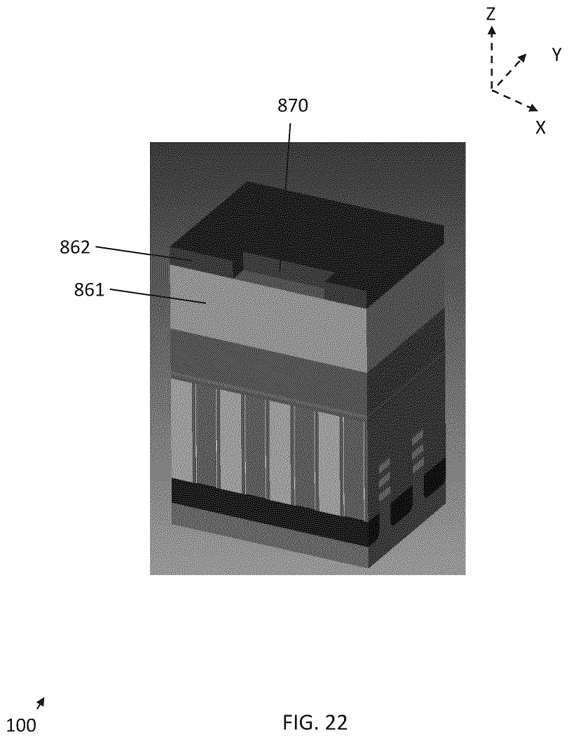

In FIG. 22, the middle layer 862 is etched through the opening 870, and the top layer 863 is removed.

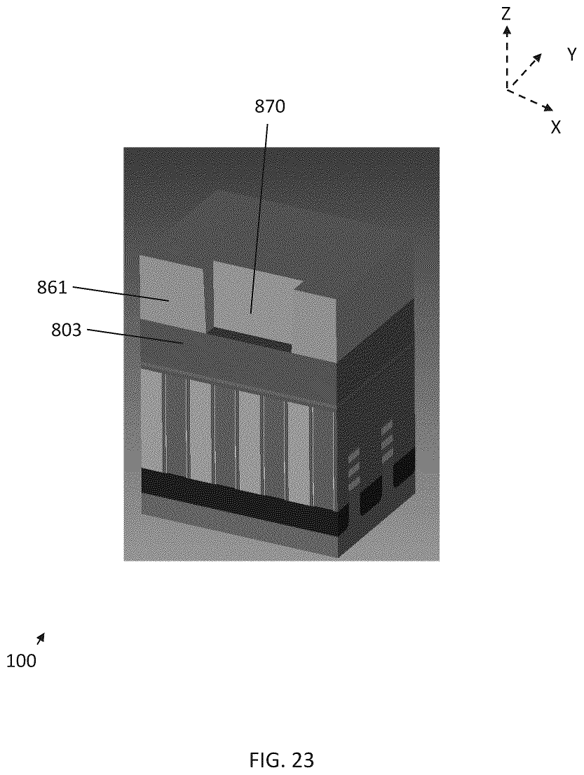

In FIG. 23, the bottom layer 861 is etched through the opening 870, and the middle layer 862 is removed.

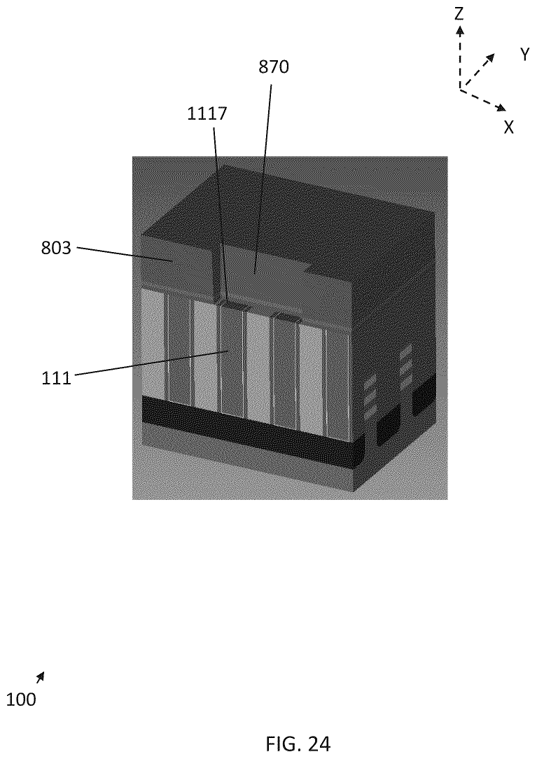

In FIG. 24, the masking layer 803 is etched through the opening 870, and the bottom layer 861 is removed. As shown, the regions 1117 of the metal lines 111 to be removed are uncovered.

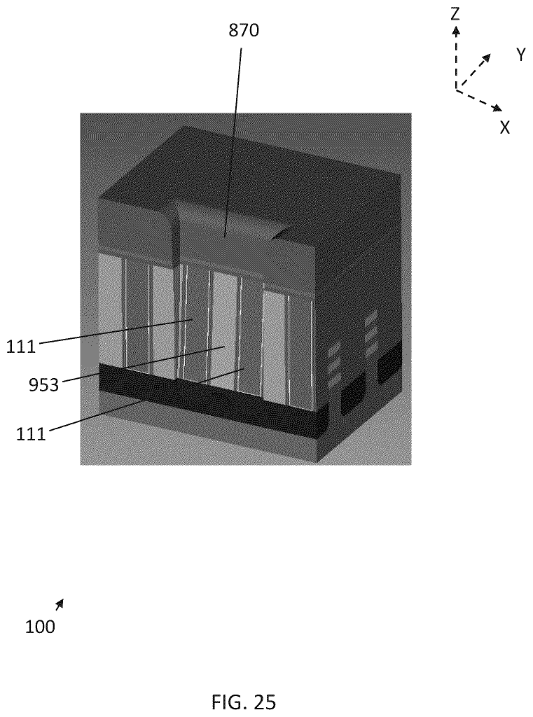

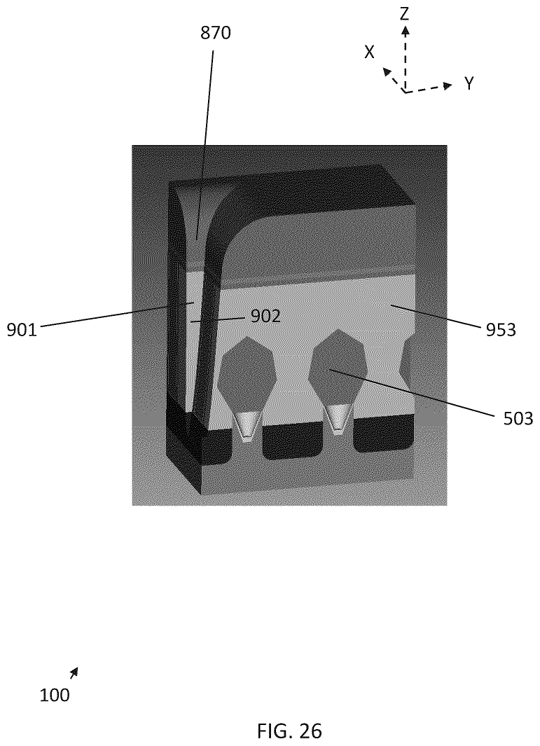

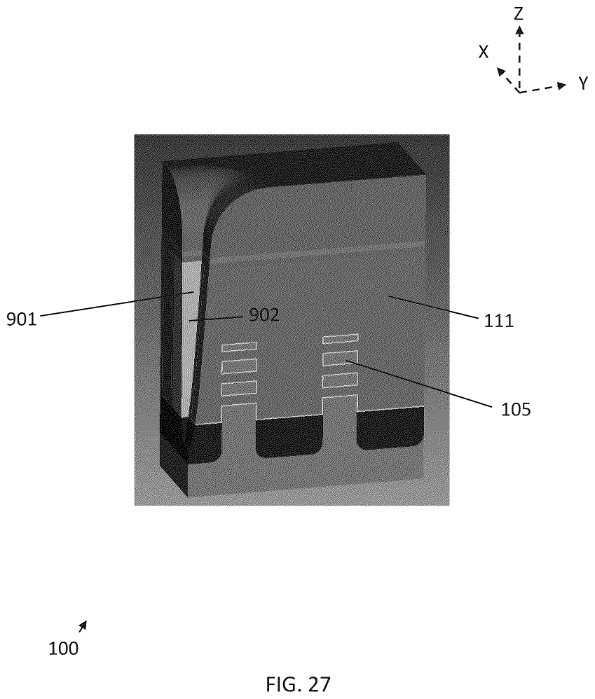

In FIG. 25, the gate lines 111, and the ILD structure 953 surrounded by the selected gate lines 111, are etched through the opening 870. FIG. 26 is a perspective view of the structure of FIG. 25, providing a Y-cut cross-section through the source/drain regions 503. FIG. 27 is a perspective view of the structure of FIG. 25, providing a Y-cut cross-section through the gate line 111.

Cross-referencing FIGS. 25-27, the trench 901 is formed with sidewalls 902. While the sidewalls 902 in FIGS. 25-27 are substantially planar, it is contemplated that the etching process for etching the trench 901 may be performed to form sidewalls 902 corresponding to the trench 901 having a desired cross-sectional shape.

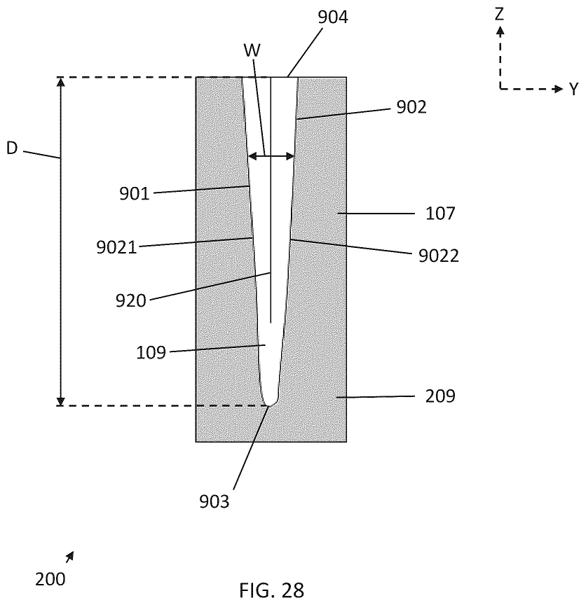

For example, FIGS. 28-30 are Y-cut cross-section views of trenches 901 in which isolation features or structures 109 are formed.

In FIG. 28, a portion 200 of device 100 is illustrated and includes a V-shaped trench 901 formed by the etching process in the methods described above. As shown, a V-shaped isolation feature 109 is formed within the V-shaped trench 901. The isolation feature may extend through the metal gate line forming metal gate electrodes 107 and into isolation region 209.

The trench extends from a trench bottom 903 to a trench opening or mouth 904. The lateral width W of the V-shaped trench 901 and of the V-shaped isolation feature 109, from sidewall 9021 to sidewall 9022 in the Y direction increases continuously from the trench bottom 903 to the trench opening or mouth 904. As shown, the lateral width increases at a constant rate from a location near the trench bottom 903 to the trench opening 904, such that the maximum width is at the trench opening 904.

As shown, the V-shaped trench 901 and isolation feature 109 have a total vertical depth D, in the Z direction, from the trench opening 904 to the trench bottom 903. In some embodiments, the V-shaped trench 901 and isolation feature 109 have a depth D to maximum width ratio of at least 3:1, such as at least 4:1, at least 5:1, at least 6:1, at least 7:1, at least 8:1, at least 9:1, or at least 10:1. In some embodiments, the V-shaped trench 901 and isolation feature 109 have a depth to maximum width ratio of no greater than 12:1, such as no greater than 10:1, no greater than 9:1, no greater than 8:1, no greater than 7:1, no greater than 6:1, no greater than 5:1, or no greater than 4:1.

In FIG. 28, the isolation feature 109 formed within the trench 901 is formed without any air gap. In certain embodiments, the isolation feature 109 may be formed with a seam 920 where the layer or layers of isolation material that form on and grow from the sidewall 9021 contact the layer or layers of isolation material that form on and grow from the sidewall 9022.

As used herein, an isolation feature 109 formed with substantially no air gap has a total air content of less than 2% by volume, such as less than 1.5%, 1%, 0.5%, 0.1%, 0.05%, or 0.01% by volume.

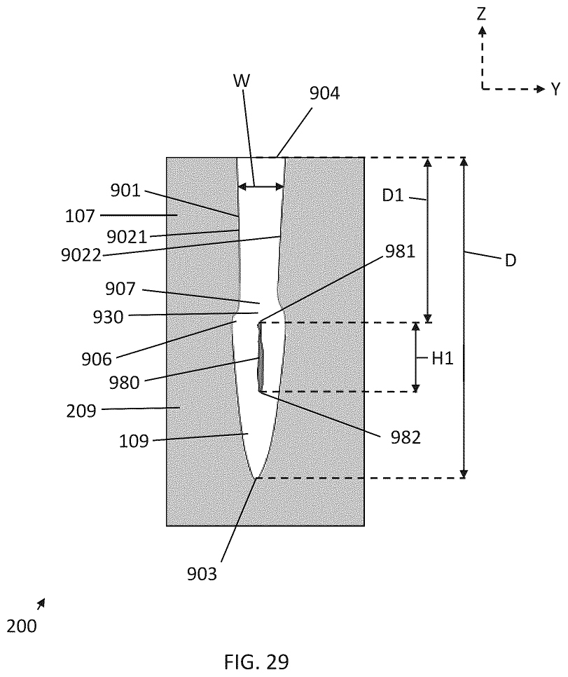

In FIG. 29, a portion 200 of device 100 is illustrated and includes a spear-shaped trench 901 formed by the etching process in the methods described above. As shown, a spear-shaped isolation feature 109 is formed within the spear-shaped trench 901. The isolation feature may extend through the metal gate line forming metal gate electrodes 107 and into isolation region 209.

The trench extends from a trench bottom 903 to a trench opening or mouth 904. The lateral width W of the spear-shaped trench 901 trench 901 and of the spear-shaped isolation feature 109, from sidewall 9021 to sidewall 9022 in the Y direction increases continuously from the trench bottom 903 to an intermediate maximum 906, decreases from the intermediate maximum to an intermediate minimum 907, and then increases from the intermediate minimum to the trench opening 904. The width at the intermediate minimum 907 is less than the width at the intermediate maximum 906 and is less than the width at the trench opening 904. In some embodiments, the width at the intermediate maximum 906 is greater than the width at the trench opening 904. In some embodiments, the width at the intermediate maximum 906 is less than the width at the trench opening 904. In some embodiments, the width at the intermediate maximum 906 is substantially equal to the width at the trench opening 904.

As shown, the spear-shaped trench 901 and isolation feature 109 have a total vertical depth D, in the Z direction, from the trench opening 904 to the trench bottom 903. In some embodiments, the spear-shaped trench 901 has a depth D2 to maximum width ratio of at least 3:1, such as at least 4:1, at least 5:1, at least 6:1, at least 7:1, at least 8:1, at least 9:1, or at least 10:1. In some embodiments, the spear-shaped trench 901 has a depth to maximum width ratio of no greater than 12:1, such as no greater than 10:1, no greater than 9:1, no greater than 8:1, no greater than 7:1, no greater than 6:1, no greater than 5:1, or no greater than 4:1.

In FIG. 29, the isolation feature 109 formed within the trench 901 is formed with a small air gap 980. Specifically, the small air gap 980 is enclosed when the layer or layers of isolation material that form on and grow from the sidewall 9021 contacts the layer or layers of isolation material that form on and grow from the sidewall 9022 at a bottleneck location 930 above the small air gap 980.

As used herein, an isolation feature 109 formed with a small air gap has a total air content of greater than 2% by volume, such as greater than 3%, 4%, 5%, 6%, 7%, 8%, 9%, 10%, 11%, 12%, 13%, 14%, 15%, 16%, 17%, 18%, 19%, or 20% by volume. As used herein, an isolation feature 109 formed with a small air gap has a total air content of less than 25% by volume, such as less than 20%, 19%, 18%, 17%, 16%, 15%, 14%, 13%, 12%, 11%, 10%, 9%, 8%, 7%, 6%, 5%, 4%, or 3% by volume.

The vertical height of air gap 980 may be selected such that the isolation feature 109 is formed with the air gap 980 with the selected vertical height. As shown, the air gap 980 has a vertical height H1, in the Z direction, from an air gap top 981 to an air gap bottom 982. As used herein, a small air gap has a vertical height H1 of at least one tenth of the total depth D, i.e., 0.1 (D), such as at least 0.2 (D), 0.3 (D), or 0.4 (D). As used herein, a small air gap has a vertical height H1 no more than 0.5 (D), such as no more than 0.4 (D), 0.3 (D), or 0.2 (D).

The depth of air gap 980 may be selected such that the isolation feature 109 is formed with the air gap 980 at the selected depth. For example, the air gap top 981 may be desired at a selected vertical depth D1, in the Z direction, from the trench opening 904.

In certain embodiments, depth D1 is at least one-tenth of the total depth D, i.e., 0.1 (D), such as at least 0.2 (D), 0.3 (D), 0.4 (D), 0.5 (D), 0.6 (D), 0.7 (D), or 0.8 (D). In certain embodiments, depth D1 is no more than 0.9 (D), such as no more than 0.8 (D), 0.7 (D), 0.6 (D), 0.5 (D), 0.4 (D), 0.3 (D), or 0.2 (D).

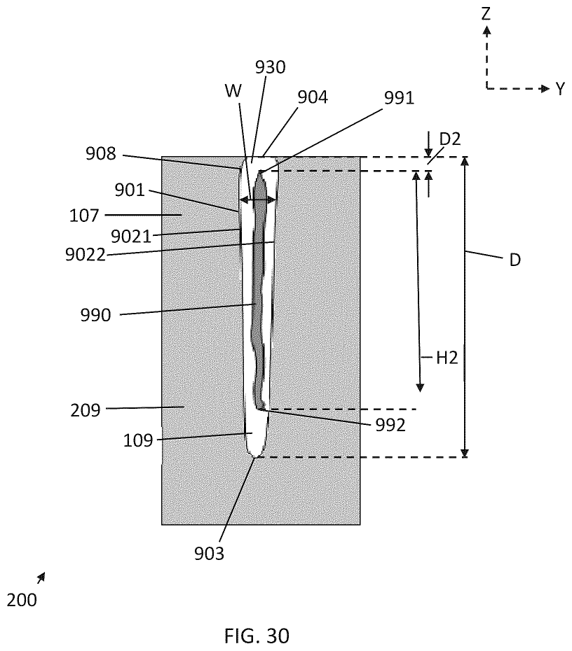

In FIG. 30, a portion 200 of device 100 is illustrated and includes a carrot-shaped trench 901 formed by the etching process in the methods described above. As shown, a carrot-shaped isolation feature 109 is formed within the carrot-shaped trench 901. The isolation feature may extend through the metal gate line forming metal gate electrodes 107 and into isolation region 209.

The trench extends from a trench bottom 903 to a trench opening or mouth 904. The lateral width W of the carrot-shaped trench 901 and of the carrot-shaped isolation feature 109, from sidewall 9021 to sidewall 9022 in the Y direction increases continuously from the trench bottom 903 to an upper location 908, and decreases from the upper location 908 to the trench opening 904. As shown, the lateral width of the trench 901 increases quickly from the trench bottom 903 and then slows to a constant increase to the upper location 908. In this manner, a carrot shape is defined.

As shown, the carrot-shaped trench 901 and isolation feature 109 have a total vertical depth D, in the Z direction, from the trench opening 904 to the trench bottom 903. In some embodiments, the carrot-shaped trench 901 has a depth D to maximum width ratio of at least 3:1, such as at least 4:1, at least 5:1, at least 6:1, at least 7:1, at least 8:1, at least 9:1, or at least 10:1. In some embodiments, the carrot-shaped trench 901 has a depth to maximum width ratio of no greater than 12:1, such as no greater than 10:1, no greater than 9:1, no greater than 8:1, no greater than 7:1, no greater than 6:1, no greater than 5:1, or no greater than 4:1.

In FIG. 30, the isolation feature 109 formed within the trench 901 is formed with a full or large air gap 990. Specifically, the full air gap 990 is enclosed when the layer or layers of isolation material that form on and grow from the sidewall 9021 contacts the layer or layers of isolation material that form on and grow from the sidewall 9022 at a bottleneck location 930 above the full air gap 990.

As used herein, an isolation feature 109 formed with a full air gap 990 has a total air content of greater than 20% by volume, such as greater than 25%, 30%, 35%, 40%, 45%, or 50% by volume. As used herein, an isolation feature 109 formed with a full air gap 990 has a total air content of less than 90% by volume, such as less than 80%, 70%, 60%, 55%, 50%, 45%, 40%, 30%, or 25% by volume.

The vertical height of air gap 990 may be selected such that the isolation feature 109 is formed with the air gap 990 with the selected vertical height. As shown, the air gap 990 has a vertical height H2, in the Z direction, from an air gap top 991 to an air gap bottom 992. As used herein, a full air gap has a vertical height H2 of at least one half of the total depth D, i.e., 0.5 (D), such as at least 0.6 (D), 0.7 (D), 0.8 (D), or 0.9 (D). As used herein, a full air gap has a vertical height H2 no more than 0.95 (D), such as no more than 0.9 (D), 0.8 (D), 0.7 (D), or 0.6 (D).

The depth of air gap 990 may be selected such that the isolation feature 109 is formed with the air gap 990 at the selected depth. For example, the air gap top 991 may be desired at a selected vertical depth D2, in the Z direction, from the trench opening 904.

In certain embodiments, depth D2 is at least one-twentieth of the total depth D, i.e., 0.05 (D), such as at least 0.1 (D), 0.2 (D), 0.3 (D), 0.4 (D), or 0.5 (D). In certain embodiments, depth D2 is no more than 0.5 (D), such as no more than 0.4 (D), 0.3 (D), 0.2 (D), or 0.1 (D).

As described herein, methods for providing isolation features having desirable properties are provided. Isolation features may be used to isolate adjacent metal gate structures or electrodes. The isolation features may be formed with methods optimized for yield, with methods optimized for forming low effective capacitance isolation features, or methods that balance yield and effective capacitance performance.

A method for isolating a metal gate includes forming a gate line over a semiconductor substrate; patterning a mask over the gate line, wherein an opening in the mask is located over a region of the gate line to be removed; performing an etching process through the opening to form a trench; and forming an isolation feature in the trench, wherein the isolation feature is selectively formed with no air gap, with a small air gap, or with a full air gap.

In certain embodiments of the method, the gate line is a dummy gate line, and the method further includes: after forming the isolation feature in the trench, removing the dummy gate line to form a gate cavity; and forming a metal gate structure in the gate cavity and adjacent to the isolation feature.

In certain embodiments of the method, the gate line is a metal gate line, and the method further includes: forming a dummy gate line over the semiconductor substrate; forming an interlayer dielectric adjacent to the dummy gate line; and removing the dummy gate line to form a gate cavity; wherein forming the gate line over the semiconductor substrate includes forming the metal gate line in the gate cavity.

In certain embodiments of the method, performing the etching process through the opening to form the trench includes forming a V-shaped trench; and forming the isolation feature in the trench includes forming the isolation feature with no air gap.

In certain embodiments of the method, performing the etching process through the opening to form the trench includes forming a spear-shaped trench; and forming the isolation feature in the trench includes forming the isolation feature with a small air gap.

In certain embodiments of the method, performing the etching process through the opening to form the trench includes forming a carrot-shaped trench; and forming the isolation feature in the trench includes forming the isolation feature with a full air gap.

In certain embodiments of the method, forming the isolation feature in the trench includes depositing a single layer of isolation material.

In certain embodiments of the method, forming the isolation feature in the trench includes depositing multiple layer of isolation material to form a multi-layer isolation feature.

In certain embodiments of the method, forming the isolation feature in the trench includes performing a deposition process to deposit isolation material in the trench, and the method further includes controlling the etching process and the deposition process to form a selected air gap at a desired depth within the isolation feature.

In one embodiment, a method includes designing a layout of an integrated circuit including a device including a first gate structure and a second gate structure separated by an isolation feature; determining a desired device performance condition and/or a desired process yield condition; selecting a structure of the isolation feature to provide the desired device performance condition, wherein the structure of the isolation feature includes a selected shape; and performing an integrated circuit fabrication process including: forming a gate line over a semiconductor substrate; performing an etching process to remove a portion of the gate line and form a trench with the selected shape; and forming an isolation feature in the trench, wherein the isolation feature is selectively formed with no air gap, with a small air gap, or with a full air gap.

In certain embodiments of the method, the selected shape is a V-shape; and forming the isolation feature in the trench includes forming the isolation feature with no air gap.

In certain embodiments of the method, the selected shape is a spear-shape; and forming the isolation feature in the trench includes forming the isolation feature with a small air gap.

In certain embodiments of the method, the selected shape is a carrot-shape; and forming the isolation feature in the trench includes forming the isolation feature with a full air gap.

In certain embodiments of the method, the selected shape is a carrot-shape; and forming the isolation feature in the trench includes forming the isolation feature with a full air gap.

In certain embodiments of the method, forming the isolation feature in the trench includes depositing multiple layers of isolation material or materials to form a multi-layer isolation feature.

In certain embodiments of the method, the structure of the isolation feature includes a selected depth of an air gap within the isolation feature; and forming the isolation feature in the trench includes forming the isolation feature with a small air gap or with a full air gap at the selected depth.

In another embodiment, a method includes determining a desired performance of an isolation feature based on isolation feature shape and based on a selected size and selected depth of an air gap therein; etching a gate line to form a trench separating the gate line into a first gate structure and a second gate structure; and forming the isolation feature in the trench, wherein the isolation feature has the isolation feature shape and an air gap with the selected size and located at the selected depth.

In certain embodiments of the method, etching the gate line to form the trench includes forming a V-shaped trench, a spear-shaped trench, or a carrot-shaped trench.

In certain embodiments of the method, the gate line is a dummy gate line, the first gate structure is a first dummy gate structure, and the second gate structure is a second dummy gate structure, and wherein the method further includes, after forming the isolation feature in the trench, removing the first dummy gate structure to form a first gate cavity; and forming a first metal gate structure in the first gate cavity and adjacent to the isolation feature.

In certain embodiments of the method, the gate line is a metal gate line, the first gate structure is a first dummy gate structure, and the second gate structure is a second dummy gate structure, and the method further includes forming a dummy gate line over a semiconductor substrate; forming an interlayer dielectric adjacent to the dummy gate line; removing the dummy gate line to form a gate cavity; and forming the metal gate line in the gate cavity before etching the gate line to form the trench.

In another embodiment, an integrated circuit device includes a semiconductor substrate; a first gate structure and a second gate structure located over the semiconductor substrate and aligned in a line; and an isolation feature located between and separating the first gate structure and the second gate structure, wherein the isolation feature has a selected shape and includes an air gap having a selected size.

In certain embodiments of the integrated circuit, the selected shape is a spear-shape, and the selected size is a small air gap.

In certain embodiments of the integrated circuit, the selected shape is a carrot-shape, and the selected size is a full air gap.

In certain embodiments of the integrated circuit, the isolation feature has a total depth, and the air gap has a height of at least one half of the total depth.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for isolating a metal gate, the method comprising:
forming a gate line over a semiconductor substrate;
patterning a mask over the gate line, wherein an opening in the mask is located over a region of the gate line to be removed;
performing an etching process through the opening to form a trench; and
forming an isolation feature in the trench, wherein the isolation feature is selectively formed with no air gap, with a small air gap, or with a full air gap.

2. The method of claim 1, wherein the gate line is a dummy gate line, and wherein the method further comprises:
after forming the isolation feature in the trench, removing the dummy gate line to form a gate cavity; and
forming a metal gate structure in the gate cavity and adjacent to the isolation feature.

3. The method of claim 1, wherein the gate line is a metal gate line, and wherein the method further comprises:
forming a dummy gate line over the semiconductor substrate;
forming an interlayer dielectric adjacent to the dummy gate line; and
removing the dummy gate line to form a gate cavity;
wherein forming the gate line over the semiconductor substrate comprises forming the metal gate line in the gate cavity.

4. The method of claim 1, wherein:
performing the etching process through the opening to form the trench comprises forming a V-shaped trench; and
forming the isolation feature in the trench comprises forming the isolation feature with no air gap.

5. The method of claim 1, wherein:
performing the etching process through the opening to form the trench comprises forming a spear-shaped trench; and
forming the isolation feature in the trench comprises forming the isolation feature with a small air gap.

6. The method of claim 1, wherein:
performing the etching process through the opening to form the trench comprises forming a carrot-shaped trench; and
forming the isolation feature in the trench comprises forming the isolation feature with a full air gap.

7. The method of claim 1, wherein:
forming the isolation feature in the trench comprises depositing a single layer of isolation material.

8. The method of claim 1, wherein:
forming the isolation feature in the trench comprises depositing multiple layer of isolation material to form a multi-layer isolation feature.

9. The method of claim 1, wherein forming the isolation feature in the trench comprises performing a deposition process to deposit isolation material in the trench, and wherein the method further comprises controlling the etching process and the deposition process to form a selected air gap at a desired depth within the isolation feature.

10. A method comprising:
designing a layout of an integrated circuit including a device comprising a first gate structure and a second gate structure separated by an isolation feature;
determining a desired device performance condition and/or a desired process yield condition;
selecting a structure of the isolation feature to provide the desired device performance condition, wherein the structure of the isolation feature comprises a selected shape; and
performing an integrated circuit fabrication process comprising:
forming a gate line over a semiconductor substrate;
performing an etching process to remove a portion of the gate line and form a trench with the selected shape; and
forming an isolation feature in the trench, wherein the isolation feature is selectively formed with no air gap, with a small air gap, or with a full air gap.

11. The method of claim 10, wherein:
the selected shape is a V-shape; and
forming the isolation feature in the trench comprises forming the isolation feature with no air gap.

12. The method of claim 10, wherein:
the selected shape is a spear-shape; and
forming the isolation feature in the trench comprises forming the isolation feature with a small air gap.

13. The method of claim 10, wherein:
the selected shape is a carrot-shape; and
forming the isolation feature in the trench comprises forming the isolation feature with a full air gap.

14. The method of claim 10, wherein:
the selected shape is a carrot-shape; and
forming the isolation feature in the trench comprises forming the isolation feature with a full air gap.

15. The method of claim 10, wherein forming the isolation feature in the trench comprises depositing multiple layers of isolation material or materials to form a multi-layer isolation feature.

16. The method of claim 10, wherein:
the structure of the isolation feature comprises a selected depth of an air gap within the isolation feature; and
forming the isolation feature in the trench comprises forming the isolation feature with a small air gap or with a full air gap at the selected depth.

17. An integrated circuit device comprising:
a semiconductor substrate;
a first gate structure and a second gate structure located over the semiconductor substrate and aligned in a line; and
an isolation feature located between and separating the first gate structure and the second gate structure, wherein the isolation feature has a selected shape and includes an air gap having a selected size.

18. The integrated circuit device of claim 17, wherein the selected shape is a spear-shape, and wherein the selected size is a small air gap.

19. The integrated circuit device of claim 17, wherein the selected shape is a carrot-shape, and wherein the selected size is a full air gap.

20. The integrated circuit device of claim 17, wherein the isolation feature has a total depth, and wherein the air gap has a height of at least one half of the total depth.
